(19) United States
(12) Patent Application Publication
(10) Pub. No.: US 2008/0001605 A1
(43) Pub. Date: Jan. 3, 2008

(54) Voltage detecting regulator with O2 sensor

(76) Inventor: Loong-Chiang Hu, Wurih Township (TW)

Correspondence Address: EGBERT LAW OFFICES, 412 MAIN STREET, 7TH FLOOR, HOUSTON, TX, 77002, US

(21) Appl. No.: 11/454,564

(22) Filed: Jun. 19, 2006

(51) Int. Cl. G01R 31/08

(52) U.S. Cl. 324/522

(57) ABSTRACT

The present invention provides a voltage detecting regulator with O₂ sensor, and this regulating device uses a voltage detecting unit and a regulating unit. The voltage detecting unit detects the feedback voltage of the O₂ Sensor and adjusts the bias voltage by manual or automatic control. The abnormality of the feedback voltage of the O₂ Sensor can be restored by the regulating unit of the present invention to maintain the normal state of air-fuel ratio, to reduce the environmental pollution, and to achieve the best air-fuel ratio. By adding the regulating device of the present invention, users may compensate for the feedback voltage of the O₂ Sensor using the regulating unit, so that the air-fuel ratio may be adjusted according to the special circumstances to meet diversified demands.

### RELATED U.S. APPLICATIONS

Not applicable.

### STATEMENT REGARDING FEDERALLY SPONSORED RESEARCH OR DEVELOPMENT

Not applicable.

### REFERENCE TO MICROFICHE APPENDIX

Not applicable.

### FIELD OF THE INVENTION

The present invention relates generally to a structure of an O₂ sensor for cars, and more particularly to using detection of feedback voltage in the O₂ Sensor to adjust the air-to-fuel ratio of the vehicle.

### BACKGROUND OF THE INVENTION

The O₂ Sensor is a device in a vehicle to detect the oxygen level from the exhaust, which sends a signal back to the computer of the vehicle to correct the fuel flow rate in order to maintain exhaust control.

The O₂ Sensor is usually placed on the converging section of the exhaust manifold and is made of ZrO₂. When the temperature of the exhaust is higher than the predetermined temperature, usually 400° F., voltage is created because the oxygen concentration inside ZrO₂ is different than the oxygen concentration in the exhaust. The bigger the difference, the higher the voltage output is, and vice versa. Because of this data, the computer is able to tell the air-fuel ratio by the change in voltage.

When the O₂ Sensor is in operation, the feedback voltage needed is very weak, only 0.1-0.9 volt. However, because the resistance of the ZrO₂ of the O₂ sensor is quite high, it has a slight electric leakage problem, such as external electric wave interruption or production control. There is a loss of the accuracy of the output, and expected exhaust control is unable to be achieve. By so doing, uneven fuel and oil consumption rates are caused, and the effort towards environmental improvement is compromised. There is also an energy waste problem.

Moreover, after the feedback voltage of the O₂ Sensor is transmitted to car computer, the feedback voltage is checked by the car computer automatically. Thus, after the O₂ Sensor is set at the manufacturer, no one is able to adjust the air-fuel ratio.

The original setting from the manufacturer has to be modified because of the following circumstances:
1. The car may overheat because of long up hill climbs. The car must increase the fuel ratio to cool the car.
2. Because the O₂ sensor is lightweight, a strong force output is not needed to reduce the fuel ratio and reduce the oil consumption.
3. Because the O₂ Sensor is overused, insufficient feedback voltage and increases the fuel oil consumption are caused.
4. ZrO₂ of the O₂ sensor is worn out naturally or becomes defective when not repaired by the manufacturer.

Thus, the conventional O₂ sensor is not adjustable, which makes the problems hard to solve, and the conventional O₂ sensor lacks practicality.

The biggest disadvantage of the O₂ sensor is that the sensor loses the accuracy of the output and becomes unable to achieve the objective of exhaust control, causing the vehicle to release toxic gas. Looking at such a big area, the exhaust pollutes the environment, which is an important subject that needed to be addressed.

Thus, to overcome the aforementioned problems of the prior art, it would be an advancement in the art to provide an improved structure that can significantly improve the efficacy.

To this end, the inventor has provided the present invention of practicability after deliberate design and evaluation based on years of experience in the production, development and design of related products.

### BRIEF SUMMARY OF THE INVENTION

The regulating device A disclosed in the present invention uses voltage detecting unit 10 and a regulating unit 20. The voltage detecting unit 10 detects the feedback voltage of the O₂ Sensor 06 and adjusts the bias voltage by manual or automatic control. Therefore, the abnormality of the feedback voltage of the O₂Sensor 06 can be restored by regulating unit A of the present invention to maintain the normal state of air-fuel ratio, to reduce the environmental pollution and to achieve the best air-fuel ratio. By adding the regulating device A of the present invention, users may compensate for the feedback voltage of the O₂Sensor 06 using the regulating unit 20, so that when the car owner and the garage adjust the air-fuel ratio, according to the special circumstances to meet the diversified demand.

Moreover, the regulating device A mentioned in the present invention can use a display unit 30 to display the feedback voltage of the O₂Sensor 06 and the bias voltage after adjusting the regulating unit 20, so that driver can detect the operation of the O₂Sensor 06 at any time.

Although the invention has been explained in relation to its preferred embodiment, it is to be understood that many other possible modifications and variations can be made without departing from the spirit and scope of the invention as hereinafter claimed.

### BRIEF DESCRIPTION OF THE SEVERAL VIEWS OF THE DRAWINGS

FIG. 1 shows a schematic view of the present invention.

FIG. 2 shows another schematic view in block illustration of the present invention.

FIG. 3 shows a schematic view of the circuit view of the present invention.

FIG. 4 shows still another schematic view of the present invention.

### DETAILED DESCRIPTION OF THE INVENTION

The features and the advantages of the present invention will be more readily understood upon a thoughtful deliberation of the following detailed description of a preferred embodiment of the present invention with reference to the accompanying drawing.

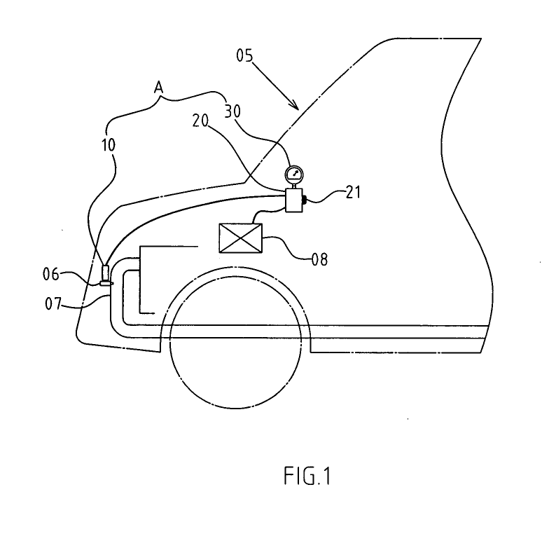

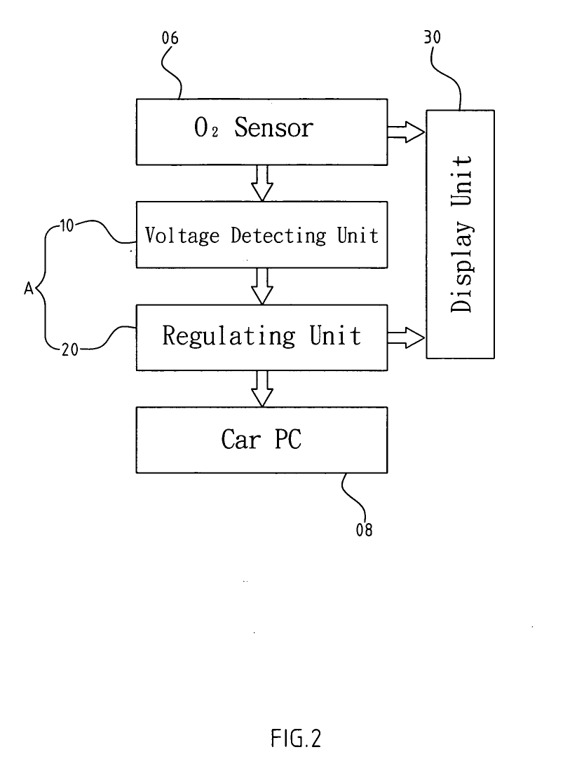

As shown in FIGS. 1 and 2, there is the preferred embodiment of the voltage detecting regulator with O₂Sensor, except that this embodiment is for description only and that it is not intended to limit the claims.

The detecting regulator A includes a voltage detecting unit 10, as shown in FIG. 1. The voltage detecting unit 10 is connected with the O₂Sensor 06 of the car 05 to detect the feedback voltage of the O₂Sensor 06. The O₂Sensor 06 of the present embodiment is placed on the converging section of the exhaust manifold 07 of the car 05.

A regulating unit 20 is connected to the voltage detecting unit 10, and the regulating unit 20 can compensate the positive or negative value for the feedback voltage of the O₂Sensor 06 by bias voltage. The regulating unit 20 is connected to the car PC computer 08 and transmits the feedback voltage to the car PC computer 08.

A display unit 30 shows the feedback voltage of the O₂Sensor 06, and a bias voltage after adjustment by the regulating unit 20. The display unit 30 can be an analog pressure meter or LCD screen. The display unit 30 can be placed in the car 05 where it is easily seen, such as in the driver seat, so that the driver can check the operation of O₂ Sensor 06 at any time.

The bias voltage of the regulating unit 20 can be manual, and it can also be automatic. When the bias voltage is manual, the regulating unit 20 can have a control component 21 for manual adjustment, such as knob, key, and sticks. The automatic control mentioned herein can have a standard voltage value set in the regulating unit 20. When the feedback voltage of the O₂Sensor 06 is lower than a standard voltage value, the PC computer compensates for the positive value automatically. When the feedback voltage of the O₂Sensor 06 is higher than a standard voltage value, the PC computer compensates for the negative value automatically. By doing so, the feedback voltage of the O₂Sensor 06 is adjusted automatically.

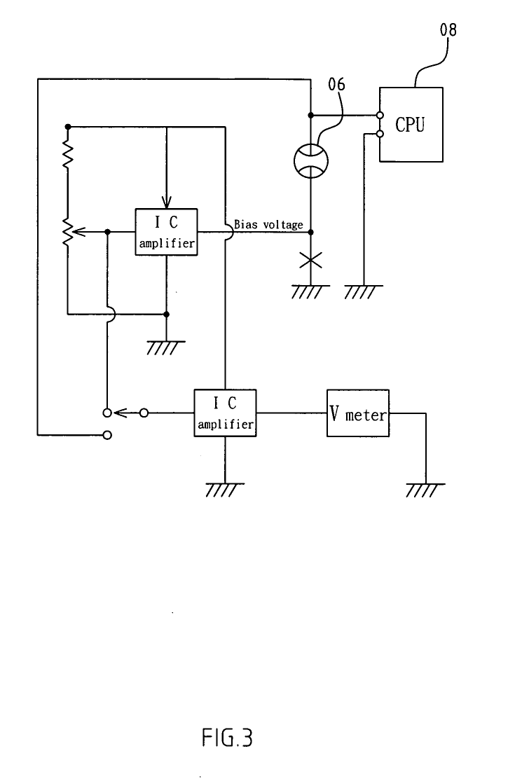

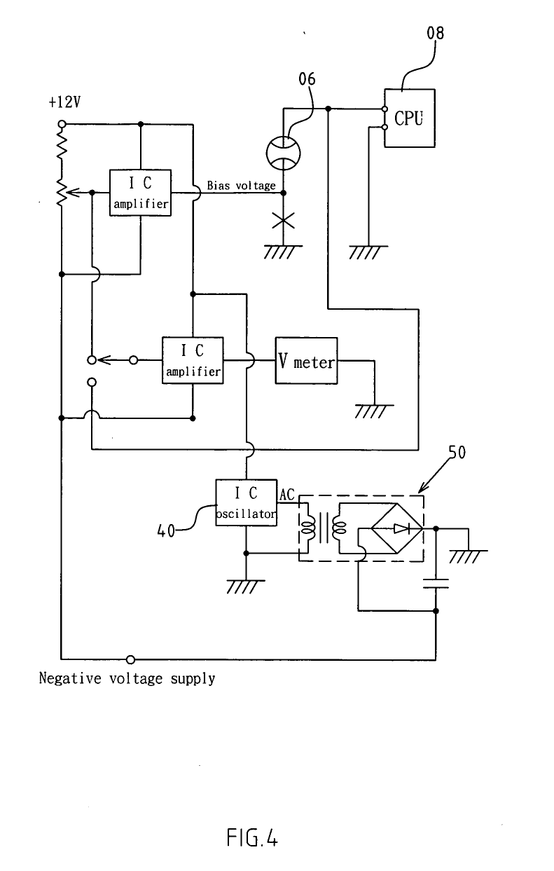

The circuit panel, when the present invention is being operated, is shown in FIGS. 3 and 4. The one shown in FIG. 3 reveals the circuit that can only generate bias voltage, and the one shown in FIG. 4 shows the circuit that can generate positive and negative bias voltage. An IC oscillator 40 and the rectifying transformer circuit 50 are added to supply the negative voltage.

Through the above structure, the operation of the present invention disclosed is explained herein.

When the O₂Sensor is working and generating feedback voltage, the voltage detecting unit 10 starts detecting the feedback voltage of the O₂Sensor 06 and adjusting bias voltage by adjusting the regulating unit 20 for abnormal feedback voltage. The regulating unit 20 compensates for a positive value or negative value to restore the original feedback voltage to keep the air-fuel ration normal. The feedback voltage of the O₂Sensor and the bias voltage after adjustment by the regulating unit 20 can be displayed by the display unit 30 for the driver to detect. When the bias voltage of the regulating unit 20 is manual control, users may adjust the bias voltage for the control component 31 by the regulating unit 20 under various circumstances mentioned herein, such as when the vehicle is going up hill and the engine is overheating. The air-fuel ratio is changed by compensating the feedback voltage of the O₂Sensor 06, this feature allowing a user and manufacturers to meet the diversified demands and practicality in applications.

Moreover, the O₂Sensor 06 disclosed in the present invention can be placed on a vehicle. Even though motorcycle technology is progressing, only the heavier motorcycles have exhaust similar to a small car; therefore there is the possibility of an added O₂Sensor on the motorcycle. For these reasons, the regulating device A mentioned above is not limited to the car use, and it may be applied to other transportation vehicles that contains O₂Sensor.

I claim:

1. A voltage detecting regulator with O₂ sensor, comprising:
a voltage detecting unit, being able to detect feedback voltage of an O₂ sensor; and
a regulating unit, being able to compensate for a positive or negative value of said feedback voltage by bias voltage.

2. The voltage detecting regulator defined in claim 1, wherein said bias voltage of said regulating unit is manual or automatic.

3. The voltage detecting regulator defined in claim 2, wherein said regulating unit has a control component when said bias voltage is manual.

4. A voltage detecting regulator with O₂ sensor, comprising:
a voltage detecting unit, being able to detect feedback voltage of an O₂ sensor;
a regulating unit, being able to compensate for a positive or negative value of said feedback voltage by bias voltage; and
a display unit, showing said feedback voltage of the O₂ sensor and the bias voltage after adjustment by said regulating unit.

5. The voltage detecting regulator defined in claim 4, wherein said bias voltage for said regulating unit is manual or automatic.

6. The voltage detecting regulator defined in claim 4, wherein said regulating unit has a control component when said bias voltage is manual.

7. The voltage detecting regulator defined in claim 4, wherein said display unit is an analog pressure meter or LCD screen.
